(19) United States
(12) Patent Application Publication
(10) Pub. No.: US 2008/0303545 A1
(43) Pub. Date: Dec. 11, 2008

(54) Low Power and Low Noise Differential Input Circuit

(75) Inventor: James Chow, Palo Alto, CA (US)

Correspondence Address: Silicon Valley Patent Group LLP, 18805 Cox Avenue, Suite 220, Saratoga, CA, 95070, US

(73) Assignee: Huaya Microelectronics, Ltd.., San Jose, CA (US)

(21) Appl. No.: 11/758,665

(22) Filed: Jun. 5, 2007

(51) Int. Cl. H03K 19/00

(52) U.S. Cl. 326/26

(57) ABSTRACT

A differential input circuit with lower power consumption and noise is disclosed. Rather than completely discharging output nodes differential circuits, the present invention equalizes the output nodes to conserver power and to reduce noise. Specifically, an equalization circuit is coupled between the output nodes of the low power and low noise differential input circuit.

### BACKGROUND OF THE INVENTION

1. Field of the Invention

The present invention relates to differential circuits. More specifically, the present invention relates differential input circuits for low power and low noise applications.

2. Discussion of Related Art

Differential signaling as opposed to single-ended signaling transmit data on two conductors rather than a single conductor. Specifically, a “true signal” is transmitted on the first conductor and a “complementary signal” is transferred on the second conductor. Differential signaling has many advantages over single-ended signaling. For example, differential signaling has greater tolerance for ground effects, reduced noise due to rejection of common-mode interference, lower voltage requirements, faster data transfer rates, and lower power use. However, the main disadvantage of differential signaling is the expense of using two conductors rather than a single conductor.

Thus, differential signaling is typically used for specific applications such as data transmission because differential signaling allows faster transfer rates at lower power than single ended signaling and analog to digital conversion because differential signaling is more suited for capturing small swings in input signals. Generally, differential signals are converted to single ended signals for data manipulation and processing.

FIG. 1(a) shows a conventional differential latch 100 having a differential input circuit 105 and a storage element 190. A timing diagram for differential latch 100 is shown in FIG. 1(b). Differential latch 100 converts a pair of differential input signals (true input signal I_T and complementary input signal I_C) to a single ended output signal OUT. Specifically, differential input circuit 105 receives clock signal CLK, true input signal I_T and complementary input signal I_C and generates a first output signal O_1 and a second output signal O_2. Generally, the differential signals use a lower voltage than the single ended signals, thus differential input circuit 105 converts the voltage level of the differential input signals for use with single ended signals as well as providing synchronization with clock signal CLK. Specifically, differential input signal 105 includes a bias transistor 110 (P-type); a true branch 120 having an input transistor 122 (P-type), output transistors 124 (P-type) and 126 (N-type), and discharge transistor 128 (N-type); and a complementary branch 130 having an input transistor 132 (P-type), output transistors 134 (P-type) and 136 (N-type), and discharge transistor 138 (N-type).

Bias transistor 110 has a first power terminal coupled to the positive power supply VCC, a control terminal coupled to receive clock signal CLK; and a second power terminal. Input transistor 122, output transistor 124, and output transistor 126 are coupled in series between ground and the second power terminal of bias transistor 110, (i.e. the first power terminal of input transistor 122 is coupled to the second power terminal of bias transistor 110, a second power terminal of input transistor 122 is coupled to a first power terminal of output transistor 124, a second power terminal of output transistor 124 is coupled to a first power terminal of output transistor 126, and a second power terminal of output transistor 126 is coupled to ground.) True input signal I_T is applied on the control terminal of input transistor 122. For convenience and clarity a first output node ON_1 is labeled in FIG. 1(a) at the connection of the second power terminal of output transistor 124 and the first power terminal of output transistor 126. First output signal O_1 is provided at first output node ON_1. The control terminals of output transistors 124 and 126 are coupled to a second output node ON_2 (described below) to receive a second output signal ON_2. Discharge transistor 128 is coupled between first output node ON_1 and ground. Clock signal CLK is applied to the control terminal of discharge transistor 128.

Input transistor 132, output transistor 134 and output transistor 136 are coupled in series between ground and the second power terminal of bias transistor 110, (i.e. the first power terminal of input transistor 132 is coupled to the second power terminal of bias transistor 110, a second power terminal of input transistor 132 is coupled to a first power terminal of output transistor 134, a second power terminal of output transistor 134 is coupled to a first power terminal of output transistor 136, and a second power terminal of output transistor 136 is coupled to ground.) Complementary input signal I_C is applied on the control terminal of input transistor 132. For convenience and clarity a second output node ON_2 is labeled in FIG. 1(a) at the connection of the second power terminal of output transistor 134 and the first power terminal of output transistor 136. Second output signal O_2 is provided at second output node ON_2. The control terminals of output transistors 134 and 136 are coupled to a first output node ON_1 to receive first output signal ON_1. Discharge transistor 138 is coupled between true output node ON_T and ground. Clock signal CLK is applied to the control terminal of discharge transistor 138.

First output signal ON_1 and second output signal ON_2 are applied to input terminals of a storage circuit 190, which provides output signal OUT. Storage circuit 190 is typically a latch or flip-flop device, such as a SR Latch, a JK latch, etc. For example, for the timing diagram of FIG. 1(b) storage circuit 190 is an SR latch, with first output signal O_1 coupled to the reset terminal of the SR latch and second output signal O_2 coupled to the set terminal of the SR_LATCH. Table 1 provides a the well known truth table for a SR Latch.

| S | R | OUT |
|---|---|---|
| 0 | 0 | Maintain OUT |
| 0 | 1 | 0 |
| 1 | 0 | 1 |
| 1 | 1 | Invalid Inputs |

FIG. 1(b) is a simplified timing diagram for differential latch 100 using an SR latch for storage circuit 190 (as described above). For clarity, such complicating factors as propagation delay are omitted. Furthermore, the input signals are shown without rise times and fall times. However, output signals are illustrated with rise time and fall time. As illustrated in FIG. 1(b), true input signal I_T and complementary input signal I_C function at a lower voltage than the other circuits in differential latch 100, however the logic high level of true input signal I_T and complementary input signal I_C is greater than the threshold voltage of input transistors 122 and 132.

When clock signal CLK is at the inactive logic level (logic high for differential latch 100), bias transistor 110 is turned off (i.e. non-conductive) and discharge transistors 128 and 138 are turned on (i.e. conductive). Thus, the other transistors in differential latch 100 are isolated from the positive power supply VCC and first output node ON_1 and second output node ON_2 are discharged to ground through discharge transistors 128 and 138. Output transistors 124 and 134 are both turned on because output nodes ON_1 and ON_2 is at logic low when clock signal CLK is at the inactive logic level (i.e. logic high). Conversely, output transistors 126 and 136 are turned off.

At falling clock edge C11 of clock signal CLK, true input signal I_T is at logic low and complementary input signal I_C is at logic high. Thus, after falling clock edge C11, input transistor 122 is turned ON (i.e. conductive) and input transistor 132 is turned OFF (i.e. non-conductive). Furthermore, bias transistor 110 is turned on and discharge transistors 128 and 138 are turned off. Therefore, first output node ON_1 (and first output signal O_1) is pulled to logic high through bias transistor 110, input transistor 122 and output transistor 124, with a rise time R1. Furthermore, as first output node ON_1 is pulled to logic high, output transistor 134 is turned off and output transistor 136 is turned on, which keeps second output node ON_2 (and second output signal O_2) at logic low. As explained above, for the timing diagram of FIG. 1(b), storage circuit 190 is an SR latch, with first output signal O_1 coupled to the set input terminal and second output signal O_2 coupled to the reset input terminal. Thus, output signal OUT transitions to logic high when first input output signal O_1 rises to logic high.

After rising clock edge C12, bias transistor 110 is turned off and discharge transistors 128 and 138 are turned on. Therefore first output node ON_1 (and first output signal O_1) is pulled down to logic low. Second output node ON_2 (and second output signal O_2) remains at logic low. With both first output signal O_1 and second output signal O_2 low, storage circuit 290 (acting as a SR Latch) retains its current value of logic high. Thus, output signal OUT remains at logic high.

By falling clock edge C13, true input signal I_T has previously transitioned to logic high and complementary input signal I_C has previously transitioned to logic low. Thus after falling clock edge C13, input transistor 132 is turned ON (i.e. conductive) and input transistor 122 is turned OFF (i.e. non-conductive). Furthermore, bias transistor 110 is turned on and discharge transistors 128 and 138 are turned off. Therefore, second output node ON_2 (and second output signal O_2) is pulled to logic high through bias transistor 110, input transistor 132 and output transistor 134, with a rise time R1. Furthermore, as second output node ON_2 is pulled to logic high, output transistor 124 is turned off and output transistor 126 is turned on, which keeps first output node ON_1 (and first output signal O_1) at logic low. Storage circuit 190 (acting as an SR Latch) pulls output signal OUT to logic low when second output signal O_2 rises to logic high.

After rising clock edge C14, bias transistor 110 is turned off and discharge transistors 128 and 138 are turned on. Therefore first output node ON_1 (and first output signal O_1) is pulled down to logic low. Second output node ON_2 (and second output signal O_2) remains at logic low. With both first output signal O_1 and second output signal O_2, storage circuit 190 (acting as a SR Latch) retains its current value of logic low. Thus, output signal OUT remains at logic low.

At falling clock edge C15 of clock signal CLK, true input signal I_T has previously transitioned to logic low and complementary input signal I_C has previously transitioned to logic high. Thus after falling clock edge C15, input transistor 122 is turned ON (i.e. conductive) and input transistor 132 is turned OFF (i.e. non-conductive). Furthermore, bias transistor 110 is turned on and discharge transistors 128 and 138 are turned off. Therefore, first output node ON_1 (and first output signal O_1) is pulled to logic high through bias transistor 110, input transistor 122 and output transistor 124, with a rise time R1. Furthermore, as first output node ON_1 is pulled to logic high, output transistor 134 is turned off and output transistor 136 is turned on, which keeps second output node ON_2 (and second output signal O_2) at logic low. As explained above, for the timing diagram of FIG. 1(b), storage circuit 190 is an SR latch, with first output signal O_1 coupled to the set input terminal and second output signal O_2 coupled to the reset input terminal. Thus, output signal OUT transitions to logic high when first input output signal O_1 rises to logic high.

The transition of true input signal I_T to logic high at rising edge 155 and the corresponding transition of complementary input signal I_C to logic low at falling edge 156 does not change the logic states of first output signal O_1 because output transistor 126 (and discharge transistor 128) has been turned off thus the charge at output node ON_1 maintains the logic state of first output signal O_1 even though input transistor 122 is turned off. Conversely, for second output signal O_2, transistor 134 has been turned off thus, turning on input transistor 132 does not change the state at second output node ON_2.

While differential latch 100 and differential input circuit functions properly and adequately, improvements to differential latch to minimize power and noise is desirable.

### SUMMARY

Accordingly, the present invention provides a differential input circuit that consumes less power and produce less noise than conventional differential input circuits. Rather than discharging the output nodes as in conventional differential circuits, the differential input circuits of the present invention, equalize the charge on the output nodes during the inactive phase of the clock period. At the beginning of the active phase of the clock period, one of the output nodes is pulled up from the equalized charge state rather than from ground; and the other output node is discharged. Because, the output node is pulled up from a equalized charge state rather than from ground, both power consumption and noise is reduced.

Specifically, in one embodiment of the present invention, the differential input circuit includes a first input block, a second input block, a first output block, a second output block, and an equalization circuit. The first input block has a first power terminal coupled to a positive power supply, a control terminal coupled to receive a true input signal, and a second power terminal. Some embodiments of the present invention include a bias circuit between the first input block and the positive power supply. The first output block has a first power terminal coupled to the second power terminal of the first input block, a second power terminal coupled to ground, an output terminal providing a first output signal, and a control terminal. The second input block has a first power terminal coupled to a positive power supply, a control terminal coupled to receive a complementary input signal, and a second power terminal. The second output block has a first power terminal coupled to the second power terminal of the second input block, a second power terminal coupled to ground, an output terminal providing a second output signal and coupled to the control terminal of the first output block, and a control terminal coupled to the output terminal of the first output block. The first equalization circuit coupled between the output terminal of the first output block and the output terminal of the second output block.

The present invention will be more fully understood in view of the following description and drawings.

### BRIEF DESCRIPTION OF THE DRAWINGS

FIG. 1(a) is circuit diagram of a conventional differential latch.

FIG. 1(b) is a timing diagram for the differential latch of FIG. 1(a).

FIG. 2 is a block diagram of a novel differential latch with a novel differential latch in accordance with one embodiment of the present invention.

FIG. 3(a) is a circuit diagram of a novel differential latch with a novel differential latch in accordance with one embodiment of the present invention.

FIG. 3(b) is a timing diagram for the differential latch of FIG. 3(a).

### DETAILED DESCRIPTION

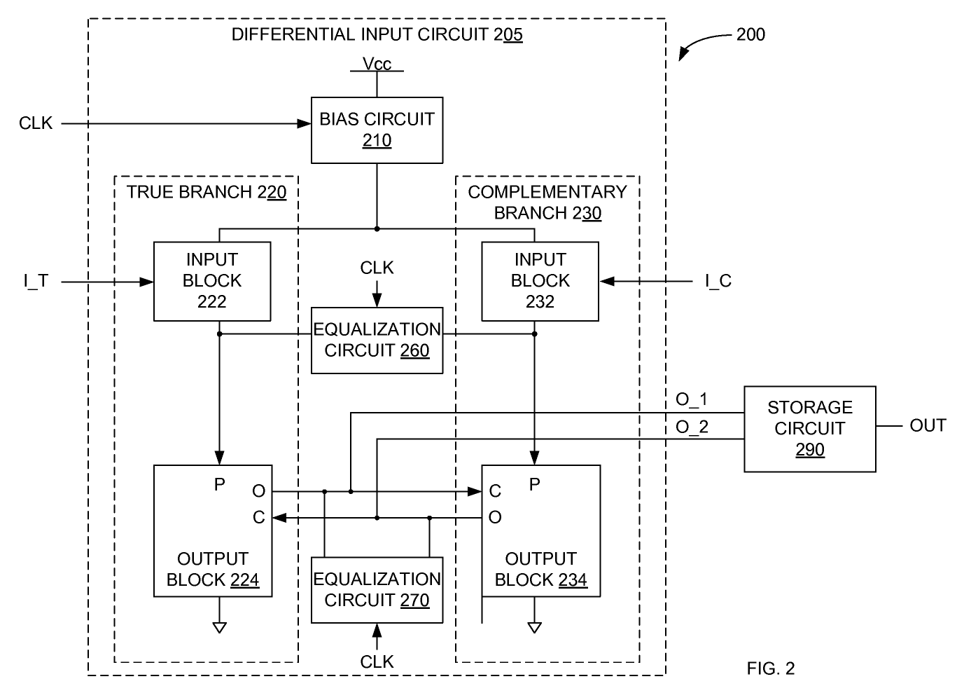

As explained above, it is desirable to improve conventional differential latches to consume less power and to produce less noise. FIG. 2 is a block diagram of a novel differential latch 200 having a novel differential input circuit 205 that consumes less power and produces less noise than conventional differential latches.

Differential latch 200 converts a pair of differential input signals (true input signal I_T and complementary input signal I_C) to a single ended output signal OUT. Specifically, differential input circuit 205 receives clock signal CLK, true input signal I_T and complementary input signal I_C and generates a first output signal O_1 and a second output signal O_2. Generally, the differential signals use a lower voltage than the single ended signals, thus differential input circuit 205 converts the voltage level of the differential input signals for use with single ended signals as well as providing synchronization with clock signal CLK. Specifically, differential input circuit 205 includes a bias circuit 210; a true branch 220 having an input block 222 and an output block 224, a complementary branch 130 having an input block 232 and an output block 234; a first equalization circuit 260; and a second equalization circuit 270.

Bias circuit 210 has a first power terminal coupled to the positive power supply VCC, a control terminal coupled to receive clock signal CLK; and a second power terminal. Input block 222 and output block 224 are coupled in series between ground and the second power terminal of bias circuit 210, (i.e. a first power terminal of input block 222 is coupled to the second power terminal of bias circuit 210, a second power terminal of input block 222 is coupled to a first power terminal (labeled P) of output block 224, and a second power terminal of output block 224 is coupled to ground.) True input signal I_T is applied on the control terminal of input block 222. First output signal O_1 is provided at output terminal (labeled O) of output block 224. Output block 224 includes an control terminal (labeled C), which is coupled to an output terminal (labeled O) of an output block 234 (described below).

Input block 232 and output block 234 are coupled in series between ground and the second power terminal of bias circuit 210, (i.e. the first power terminal of input block 232 is coupled to the second power terminal of bias block 210, a second power terminal of input block 132 is coupled to a first power terminal of output block 234, a second power terminal of output block 234 is coupled to ground.) Complementary input signal I_C is applied on the control terminal of input block 232. Output block 234 includes an output terminal (labeled O), which drives second output signal O_2, and a control terminal (labeled C) coupled to receive first output signal O_1 from output block 224. First equalization circuit 260 is coupled between the power terminals of output block 224 and output block 234 and is controlled by clock signal CLK. Second equalization circuit 270 is coupled between the output terminals of output block 224 and output block 234.

First output signal ON_1 and second output signal ON_2 are applied to input terminals of a storage circuit 290, which provides output signal OUT. Storage circuit 290 is typically a latch or flip-flop device, such as a SR Latch, a JK latch, etc.

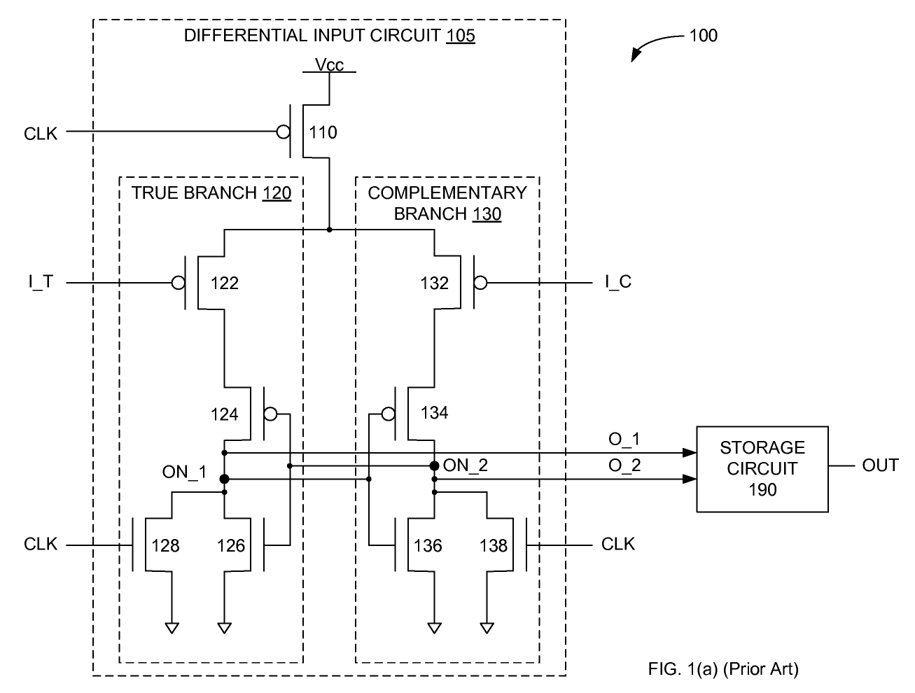

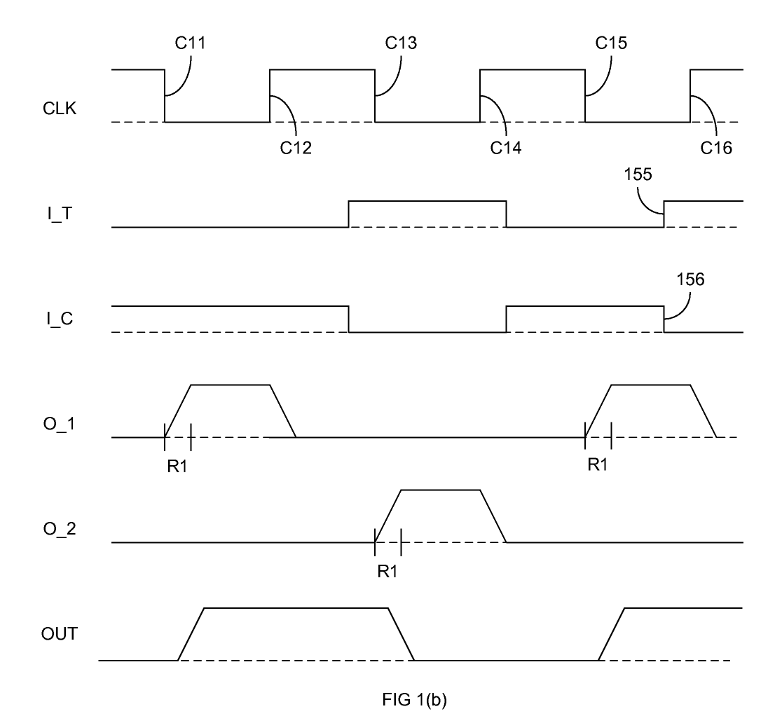

In conventional differential input circuit 105 (FIG. 1) either first output signal O_1 or output signal O_2 is at logic high during the active phase of clock signal CLK (i.e. when clock signal CLK is at the active logic level (logic low)) then both output signal O_1 and are discharged to ground during the inactive phase of clock signal CLK. Rather than discharging the output signals to ground, differential latch 200 “reuses” some the charge on the output signals to reduce power consumption. Specifically, during inactive phase of clock signal CLK, equalization circuits 260 is activated to equalize the charge at the first power terminals of output blocks 224 and 234 and equalization circuit 270 is activated to equalize the charge on the output terminals of output blocks 224 and 234. Thus, during the inactive phase of clock signal CLK, output signals O_1 and O_2 are pulled to a residual voltage level Vr. Residual voltage level Vr should be less than the threshold voltage of the transistors in storage circuit 290, output block 224 and output block 234. When clock signal CLK enters the active phase, whichever output signal that should be pulled to logic high only needs to rise from residual voltage level Vr to logic high rather than rising all the way from ground to logic high. The smaller voltage transition for differential input circuit 205 consumes less power, reduces noise and improves rise times as compared to differential input circuit 105.

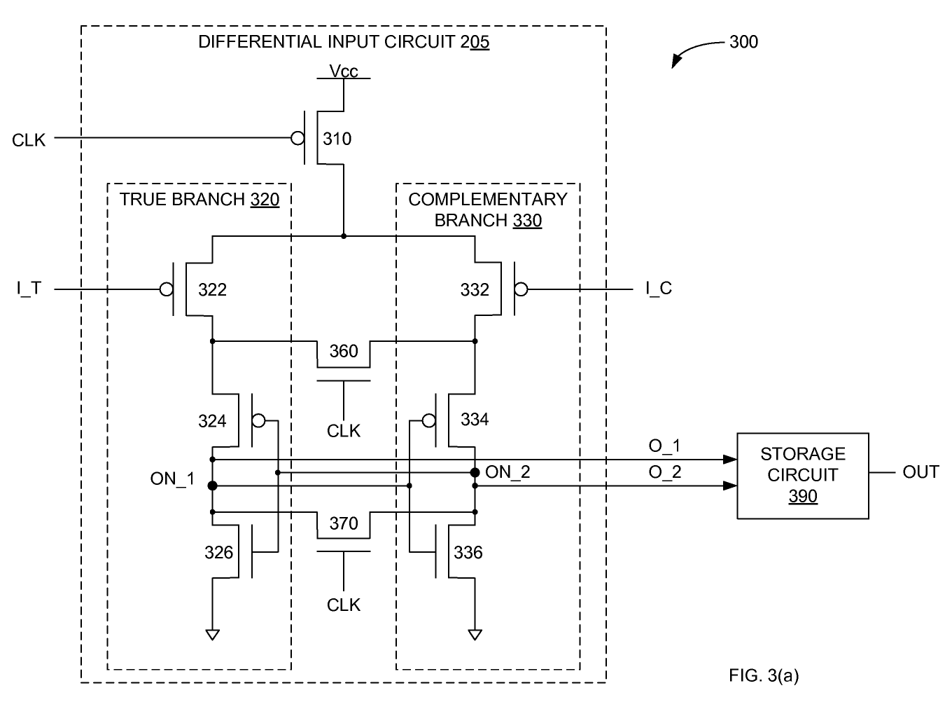

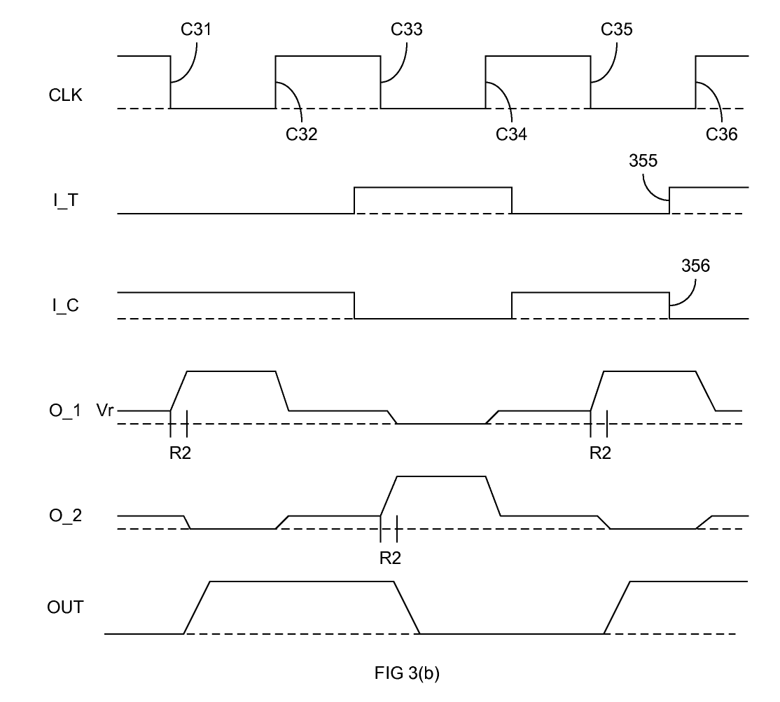

FIG. 3(a) is a detailed circuit diagram for a differential latch 300, having a differential input circuit 305 and a storage element 390, in accordance with one embodiment of the present invention. In differential latch 300 bias circuit 210 is a bias transistor 310 (P-type); input block 222 is a input transistor 322 (P-type); output block 224 includes an output transistor 324 (P-type) and an output transistor 326 (N-Type); input block 232 is an input transistor 332 (P-type), output block 234 includes an output transistor 334 (P-type) and an output transistor 336 (N-type); equalization circuit 260 is a equalization transistor 360 (N-type); and equalization circuit 270 is an equalization transistor 370 (N-type). A timing diagram for differential latch 300 is shown in FIG. 3(b). Differential latch 300 converts a pair of differential input signals (true input signal I_T and complementary input signal I_C) to a single ended output signal OUT. Specifically, differential input circuit 305 receives clock signal CLK, true input signal I_T and complementary input signal I_C and generates a first output signal O_1 and a second output signal O_2.

Specifically, in differential input circuit 305, bias transistor 310 has a first power terminal coupled to the positive power supply VCC, a control terminal coupled to receive clock signal CLK; and a second power terminal. Input transistor 322, output transistor 324, and output transistor 326 are coupled in series between ground and the second power terminal of bias transistor 310, (i.e. the first power terminal of input transistor 322 is coupled to the second power terminal of bias transistor 310, a second power terminal of input transistor 322 is coupled to a first power terminal of output transistor 324, a second power terminal of output transistor 324 is coupled to a first power terminal of output transistor 326, and a second power terminal of output transistor 326 is coupled to ground.) True input signal I_T is applied on the control terminal of input transistor 322. For convenience and clarity a first output node ON_1 is labeled in FIG. 3(a) at the connection of the second power terminal of output transistor 324 and the first power terminal of output transistor 326. First output signal O_1 is provided at first output node ON_1. The control terminals of output transistors 324 and 326 are coupled to a second output node ON_2 (described below) to receive a second output signal ON_2.

Input transistor 332, output transistor 334 and output transistor 336 are coupled in series between ground and the second power terminal of bias transistor 310, (i.e. the first power terminal of input transistor 332 is coupled to the second power terminal of bias transistor 310, a second power terminal of input transistor 332 is coupled to a first power terminal of output transistor 334, a second power terminal of output transistor 334 is coupled to a first power terminal of output transistor 336, and a second power terminal of output transistor 136 is coupled to ground.) Complementary input signal I_C is applied on the control terminal of input transistor 332. For convenience and clarity a second output node ON_2 is labeled in FIG. 3(a) at the connection of the second power terminal of output transistor 334 and the first power terminal of output transistor 336. Second output signal O_2 is provided at second output node ON_2. The control terminals of output transistors 334 and 336 are coupled to a first output node ON_1 to receive first output signal ON_1. Equalization transistor 360 is coupled between the first power terminal of output transistor 324 and the first power terminal of output transistor 334. Clock signal CLK is applied to the control terminal of equalization transistor 360. Equalization transistor 370 is coupled between first output node ON_1 and second output node ON_2. Clock signal CLK is applied to the control terminal of equalization transistor 370.

First output signal ON_1 and second output signal ON_2 are applied to input terminals of a storage circuit 390, which provides output signal OUT. Storage circuit 390 is typically a latch or flip-flop device, such as a SR Latch, a JK latch, etc. For example, for the timing diagram of FIG. 3(b) storage circuit 390 is an SR latch, with first output signal O_1 coupled to the reset terminal of the SR latch and second output signal O_2 coupled to the set terminal of the SR_LATCH.

In a particular embodiment of the present invention, using a 0.18 μm process technology with VDD equal to 1.8 volts the transistors are sized as indicated in Table 1.

| Transistor | Channel Width | Channel Length |
|---|---|---|
| 310 | 3.00 μm | 0.30 μm |
| 322 | 4.00 μm | 0.20 μm |
| 324 | 4.00 μm | 0.20 μm |
| 326 | 2.00 μm | 0.20 μm |
| 332 | 4.00 μm | 0.20 μm |
| 334 | 4.00 μm | 0.20 μm |
| 336 | 2.00 μm | 0.20 μm |
| 360 | 1.00 μm | 0.18 μm |
| 370 | 1.00 μm | 0.18 μm |

FIG. 3(b) is a simplified timing diagram for differential latch 300 using an SR latch for storage circuit 390 (as described above). For clarity, such complicating factors as propagation delays are omitted. Furthermore, the input signals are shown without rise times and fall times. However, output signals are illustrated with rise time and fall time. As illustrated in FIG. 3(b), true input signal I_T and complementary input signal I_C function at a lower voltage than the other circuits differential latch 300, however the logic high level of true input signal I_T and complementary input signal I_C is greater than the threshold voltage of input transistors 322 and 332.

When clock signal CLK is at the inactive logic level (logic high for differential latch 300), bias transistor 310 is turned off (i.e. non-conductive) and equalization transistors 360 and 370 are turned on (i.e. conductive). Thus, the other transistors in differential latch 300 are isolated from the positive power supply VCC and first output node ON_1 and second output node ON_2 are equalized to a residual voltage level Vr. Residual voltage level Vr depends on the amount of charge at output nodes ON_1 and ON_2 prior to the transition of clock signal clock from an active logic level to an inactive logic level. However, residual voltage level Vr should be lower than the threshold voltage of the transistors having control terminals coupled to first output signal O_1 or second output signal O_2. At initial power on no charge is present on either first output node ON_1 or second output node ON_2 and thus for the first activation of differential latch 300 the output signals would start from ground level rather than a residual voltage level. While clock signal CLK is at the inactive logic level, output transistors 324 and 334 are both turned on because output nodes ON_1 and ON_2 are at voltage level that is lower than the threshold voltage of output transistors 324 and 334. Conversely, output transistors 326 and 336 are turned off.

At falling clock edge C31 of clock signal CLK, true input signal I_T is at logic low and complementary input signal I_C is at logic high. Thus after falling clock edge C31, input transistor 322 is turned ON (i.e. conductive) and input transistor 332 is turned OFF (i.e. non-conductive). Furthermore, bias transistor 310 is turned on and equalization transistors 360 and 370 are turned off. Therefore, first output node ON_1 (and first output signal O_1) is pulled to logic high through bias transistor 310, input transistor 322 and output transistor 324, with a rise time R2. Furthermore, as first output node ON_1 is pulled to logic high, output transistor 334 is turned off and output transistor 336 is turned on, which pulls second output node ON_2 (and second output signal O_2) to logic low. As explained above, for the timing diagram of FIG. 3(b), storage circuit 390 is an SR latch, with first output signal O_1 coupled to the set input terminal and second output signal O_2 coupled to the reset input terminal. Thus, output signal OUT transitions to logic high when first input output signal O_1 rises to logic high.

After rising clock edge C32, bias transistor 310 is turned off and equalization transistors 360 and 370 are turned on. Therefore first output node ON_1 (and first output signal O_1) and second output node ON_2 (and second output signal O_2) are equalized to residual voltage level Vr through equalization transistor 370. With both first output signal O_1 and second output signal O_2 at residual voltage level Vr (which is below the threshold voltage of the transistors of storage circuit 390) storage circuit 390 (acting as a SR Latch) retains its current value of logic high. Thus, output signal OUT remains at logic high.

By falling clock edge C33, true input signal I_T has previously transitioned to logic high and complementary input signal I_C has previously transitioned to logic low. Thus after falling clock edge C33, input transistor 332 is turned ON (i.e. conductive) and input transistor 322 is turned OFF (i.e. non-conductive). Furthermore, bias transistor 310 is turned on and equalization transistors 360 and 370 are turned off. Therefore, second output node ON_2 (and second output signal O_2) is pulled to logic high through bias transistor 310, input transistor 332 and output transistor 334, with a rise time R2. Furthermore, as second output node ON_2 is pulled to logic high, output transistor 324 is turned off and output transistor 326 is turned on which discharges first output node ON_1 (and first output signal O_1) to logic low. Storage circuit 390 (acting as an SR Latch) pulls output signal OUT to logic low when second output signal O_2 rises to logic high.

After rising clock edge C34, bias transistor 310 is turned off and equalization transistors 360 and 370 are turned on. Therefore first output node ON_1 (and first output signal O_1) and second output node ON_2 (and second output signal O_2) are equalized at residual voltage level Vr. With both first output signal O_1 and second output signal O_2 at residual voltage level Vr (which is below the threshold voltage of the transistors of storage circuit 390), storage circuit 390 (acting as a SR Latch) retains its current value of logic low. Thus, output signal OUT remains at logic low.

At falling clock edge C35 of clock signal CLK, true input signal I_T has previously transitioned to logic low and complementary input signal I_C has previously transitioned to logic high. Thus, after falling clock edge C35, input transistor 322 is turned ON (i.e. conductive) and input transistor 332 is turned OFF (i.e. non-conductive). Furthermore, bias transistor 310 is turned on and equalization transistors 360 and 370 are turned off. Therefore, first output node ON_1 (and first output signal O_1) is pulled to logic high through bias transistor 310, input transistor 322 and output transistor 324, with a rise time R2. Furthermore, as first output node ON_1 is pulled to logic high, output transistor 334 is turned off and output transistor 336 is turned on, which discharges second output node ON_2 (and second output signal O_2) to logic low. As explained above, for the timing diagram of FIG. 3(b), storage circuit 390 is an SR latch, with first output signal O_1 coupled to the set input terminal and second output signal O_2 coupled to the reset input terminal. Thus, output signal OUT transitions to logic high when first input output signal O_1 rises to logic high.

The transition of true input signal I_T to logic high at rising edge 355 and the corresponding transition of complementary input signal I_C to logic low at falling edge 356 does not change the logic states of first output signal O_1 because output transistor 326 has been turned off thus the charge at output node ON_1 maintains the logic state of first output signal O_1 even though input transistor 322 is turned off. Conversely, for second output signal O_2, transistor 334 has been turned off thus, turning on input transistor 332 does not change the state at second output node ON_2.

Thus, differential input circuits in accordance with embodiments of the present invention reduce power consumption by equalizing the output signals to a residual voltage level Vr during the inactive phase rather than discharging the output signals to ground. Furthermore, noise is also reduced because the voltage swings of the output signals is reduced compared to conventional differential input circuits.

In the various embodiments of the present invention, novel circuits and methods have been described for creating a differential input circuit. The various embodiments of the structures and methods of this invention that are described above are illustrative only of the principles of this invention and are not intended to limit the scope of the invention to the particular embodiments described. For example, in view of this disclosure those skilled in the art can define other bias circuits, equalization circuits, input blocks, output blocks, storage circuits, and so forth, and use these alternative features to create a method, or system according to the principles of this invention. Thus, the invention is limited only by the following claims.

What is claimed is:

1. A differential input circuit comprising:
a first input block having a first power terminal coupled to a positive power supply, a control terminal coupled to receive a true input signal, and a second power terminal;
a first output block having a first power terminal coupled to the second power terminal of the first input block, a second power terminal coupled to ground, an output terminal providing a first output signal, and a control terminal;
a second input block having a first power terminal coupled to a positive power supply, a control terminal coupled to receive a complementary input signal, and a second power terminal;
a second output block having a first power terminal coupled to the second power terminal of the second input block, a second power terminal coupled to ground, an output terminal providing a second output signal and coupled to the control terminal of the first output block, and a control terminal coupled to the output terminal of the first output block; and
a first equalization circuit coupled between the output terminal of the first output block and the output terminal of the second output block.

2. The differential input circuit of claim 1, further comprising a bias circuit coupled between the first power terminal of the first input block and the positive power supply.

3. The differential input circuit of claim 2, wherein the bias circuit is also coupled between the first power terminal of the second input block and the positive power supply.

4. The differential input circuit of claim 2, wherein the bias circuit comprises a P-type bias transistor with a first power terminal coupled to the positive power supply, a second power terminal coupled to first power terminal of the first input block; and a control terminal coupled to receive a clock signal.

5. The differential input circuit of claim 1, wherein
the first input block comprises a first input transistor; and
the second input block comprises a second input transistor.

6. The differential input circuit of claim 1, wherein the first output block comprises:
a first output transistor having a first power terminal coupled to the first input block, a control terminal coupled to the control terminal of the first output block, and a second power terminal;
a second output transistor having a first power terminal coupled to the second output terminal of the first output transistor, a second power terminal coupled to ground, and a control terminal coupled to the control terminal of the first output block; and
wherein the second power terminal of the first output transistor is coupled to the output terminal of the first output block.

7. The differential input circuit of claim 6, wherein the first output transistor is a P-type transistor and the second output transistor is a N-type transistor.

8. The differential input circuit of claim 1, wherein the first equalization circuit has a control terminal coupled to a clock signal.

9. The differential input circuit of claim 1, wherein the first equalization circuit comprises an N-type transistor.

10. The differential input circuit of claim 1, further comprising a second equalization circuit coupled between the first power terminal of the first output block and the first power terminal of the second output block.

11. The differential input circuit of claim 1 coupled to a storage circuit; wherein the output terminal of the first output block is coupled to a first input terminal of the storage circuit and the output terminal of the second output block is coupled to a second input terminal of the storage circuit.

12. The differential input circuit of claim 11, wherein the storage circuit is an SR latch.

13. A differential input circuit comprising:
a first input block having a first power terminal coupled to a positive power supply, a control terminal coupled to receive a true input signal, and a second power terminal;
a first output block having a first power terminal coupled to the second power terminal of the first input block, a second power terminal coupled to ground, an output terminal providing a first output signal, and a control terminal;
a second input block having a first power terminal coupled to a positive power supply, a control terminal coupled to receive a complementary input signal, and a second power terminal;
a second output block having a first power terminal coupled to the second power terminal of the second input block, a second power terminal coupled to ground, an output terminal providing a second output signal and coupled to the control terminal of the first output block, and a control terminal coupled to the output terminal of the first output block; and
a first equalization circuit coupled between the first power terminal of the first output block and the first power terminal of the second output block.

14. The differential input circuit of claim 13, wherein
the first input block comprises a first input transistor; and
the second input block comprises a second input transistor.

15. The differential input circuit of claim 13, wherein the first output block comprises:
a first output transistor having a first power terminal coupled to the first input block, a control terminal coupled to the control terminal of the first output block, and a second power terminal;
a second output transistor having a first power terminal coupled to the second output terminal of the first output transistor, a second power terminal coupled to ground, and a control terminal coupled to the control terminal of the first output block; and
wherein the second power terminal of the first output transistor is coupled to the output terminal of the first output block.

16. The differential input circuit of claim 15, wherein the first output transistor is a P-type transistor and the second output transistor is a N-type transistor.

17. The differential input circuit of claim 13, wherein the first equalization circuit has a control terminal coupled to a clock signal.

18. The differential input circuit of claim 13, wherein the first equalization circuit comprises an N-type transistor.

19. A differential input circuit comprising:
a first input transistor having a first power terminal coupled to a positive power supply, a control terminal coupled to receive a true input signal, and a second power terminal;
a first output transistor having a first power terminal coupled to the second power terminal of the first input transistor, a second power terminal providing a first output signal, and a control terminal;
a second output transistor having a first power terminal coupled to the second poser terminal of the first output transistor, a second power terminal coupled to ground, and a control terminal coupled to the control terminal of the first output transistor;
a second input transistor having a first power terminal coupled to a positive power supply, a control terminal coupled to receive a complementary input signal, and a second power terminal;
a third output transistor having a first power terminal coupled to the second power terminal of the second input transistor, a second power terminal providing a second output signal and coupled to the control terminal of the first output transistor, and a control terminal coupled to the output terminal of the first output transistor;
a fourth output transistor having a first power terminal coupled to the second power terminal of the third output transistor, a second power terminal coupled to ground, and a control terminal coupled to the control terminal of the third output transistor; and
a first equalization transistor coupled between the second power terminal of the first output transistor and the second power terminal of the third output transistor

20. The differential input circuit of claim 19, further comprising a second equalization transistor coupled between the first power terminal of the first output transistor and the first power terminal of the third output transistor.
